(19) United States
(12) Patent Application Publication
(10) Pub. No.: US 2011/0260329 A1
(43) Pub. Date: Oct. 27, 2011

(54) SEMICONDUCTOR INTEGRATED CIRCUIT

(76) Inventor: Ji-Tai Seo, Gyeonggi-do (KR)

(21) Appl. No.: 12/833,099

(22) Filed: Jul. 9, 2010

(30) Foreign Application Priority Data
Apr. 27, 2010 (KR) 10-2010-0038911

(51) Int. Cl. H01L 23/48

(52) U.S. Cl. 257/774; 257/E23.011

(57) ABSTRACT

A semiconductor integrated circuit includes a through-chip via passing through a semiconductor chip, and an insulator arranged inside the through-chip via to electrically divide the through-chip via. Here, the divided through-chip vias may transmit different signals.

### CROSS-REFERENCE TO RELATED APPLICATION

The present application claims priority of Korean Patent Application No. 10-2010-0038911, filed on Apr. 27, 2010, which is incorporated herein by reference in its entirety.

### BACKGROUND OF THE INVENTION

Exemplary embodiments of the present invention relate to a semiconductor design technology, and more particularly, to a semiconductor integrated circuit.

Packaging technologies for semiconductor integrated circuits have been continuously developed to improve package compactness and reliability. As high-performance, miniature electric/electronic products are increasingly desired, a variety of stack package technologies are being developed.

In semiconductor industries, the term “stack” refers to a structure in which at least two semiconductor chips or packages are laminated, and through the stack package technology, products having two or more times memory capacity can be implemented. In addition, since the stack package technology can increase the memory capacity and it is advantageous in view of package density and a usage efficiency of a package area, studies and development of stack packages are being accelerated.

The stack package may be fabricated by stacking individual semiconductor chips and packaging the stacked semiconductor chips at one time, or may be fabricated by stacking packaged individual semiconductor chips. The individual semiconductor chips of the stack package may be electrically connected together through metal wires or through-silicon vias (TSVs). Specifically, the stack package may have a structure having TSVs within the semiconductor chips, and the semiconductor chips may be physically and electrically connected by the TSVs.

FIG. 1 is a perspective view illustrating the structure of a stack-packaged semiconductor integrated circuit.

Referring to FIG. 1, the semiconductor integrated circuit 100 may include a plurality of semiconductor chips 110, 120, and 130 stacked vertically, and a plurality of TSVs 140, 150, and 160. The TSVs 140, 150, and 160 pass through the plurality of semiconductor chips 110, 120, and 130 and transmit data signals and power supply signals to/from the plurality of semiconductor chips 110, 120, and 130. Here, several hundreds to several thousands of the TSVs 140, 150, and 160 may be arranged. Meanwhile, although not illustrated in detail, bump pads, which electrically connect the plurality of TSVs 140, 150, and 160, may be arranged in regions where the plurality of TSVs passing through the semiconductor chips 110, 120, and 130 are connected together.

FIG. 2A is a plan view illustrating the semiconductor integrated circuit of FIG. 1, and FIG. 2B is a side sectional view taken along line A-A′ of FIG. 2A.

For convenience of explanation, a single semiconductor chip and a single TSV passing through the semiconductor chip will be described as an example with reference to FIGS. 2A and 2B.

Referring to FIGS. 2A and 2B, the TSV 140 vertically passing through the semiconductor chip 110 may be arranged inside the semiconductor chip 110. As described above, the TSV 140 may serve as an interface for a data signal and a power supply signal and may be formed of a conductive material, e.g., a metal. Here, the TSV 140 may be formed of copper (Cu). Such a TSV 140 may transmit a single data signal or a single power supply signal.

However, the conventional semiconductor integrated circuit may have the following limitations.

Since the TSV 140 may transmit a single data signal or a single power supply signal, the number of the TSVs 140 may increase as the number of data signals and power supply signals to be transmitted increases. In practice, since several hundred to several thousand TSVs 140 may be arranged in the semiconductor chip 110, the TSVs 140 may occupy a significantly large area. In addition, because devices (for example, MOS transistors) arranged near the TSV 140 may be degraded, it may be desirable to ensure a certain area around the TSV 140 in the semiconductor chip 110. Therefore, devices may not be arranged within the area around the TSV 140, and thus as the number of the TSVs 140 increases, the entire area of the semiconductor integrated circuit may increase.

### SUMMARY OF THE INVENTION

Exemplary embodiments of the present invention are directed to a semiconductor integrated circuit which may reduce/minimize an area occupied by TSVs while maintaining the number of data signals and power supply signals transmitted between stacked semiconductor chips.

In accordance with an exemplary embodiment of the present invention, a semiconductor integrated circuit includes a through-chip via (TCV) passing through a semiconductor chip, and an insulator arranged inside the through-chip via to electrically divide the through-chip via, wherein each of the divided through-chip vias is configured to transmit different signals.

In accordance with another exemplary embodiment of the present invention, a semiconductor integrated circuit includes a semiconductor chip, a through-chip via passing through the semiconductor chip, and an insulator arranged inside the through-chip via, the insulator having a cylindrical shape in order to divide the through-chip via, wherein each of the divided through-chip vias is configured to transmit different signals.

In accordance with yet another exemplary embodiment of the present invention, a semiconductor integrated circuit includes a first through-chip via passing through a semiconductor chip, a second through-chip via passing through the semiconductor chip, wherein the second through-chip via is arranged inside the first through-chip via, a third through-chip via passing through the semiconductor chip, wherein the third through-chip via is arranged inside the second through-chip via, a first insulator arranged between the first through-chip via and the second through-chip via, and a second insulator arranged between the second through-chip via and the third through-chip via, wherein each of the through-chip vias is configured to transmit different signals.

### BRIEF DESCRIPTION OF THE DRAWINGS

FIG. 1 is a perspective view illustrating the structure of a stack-packaged semiconductor integrated circuit.

FIG. 2A is a plan view illustrating the semiconductor integrated circuit of FIG. 1.

FIG. 2B is a side sectional view taken along line A-A′ of FIG. 2A.

FIG. 3A is a plan view illustrating a semiconductor integrated circuit in accordance with an exemplary embodiment of the present invention.

FIG. 3B is a side sectional view taken along line B-B′ of FIG. 3A.

FIG. 4 is a plan view illustrating another exemplary shape of an insulator of FIGS. 3A and 3B.

FIG. 5A is a plan view illustrating a semiconductor integrated circuit in accordance with another embodiment of the present invention.

FIG. 5B is a side sectional view taken along line C-C′ of FIG. 5A.

FIG. 6 is a plan view illustrating another exemplary shape of an insulator of FIGS. 5A and 5B.

FIG. 7A is a plan view illustrating a semiconductor integrated circuit in accordance with another embodiment of the present invention.

FIG. 7B is a side sectional view taken along line D-D′ of FIG. 7A.

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

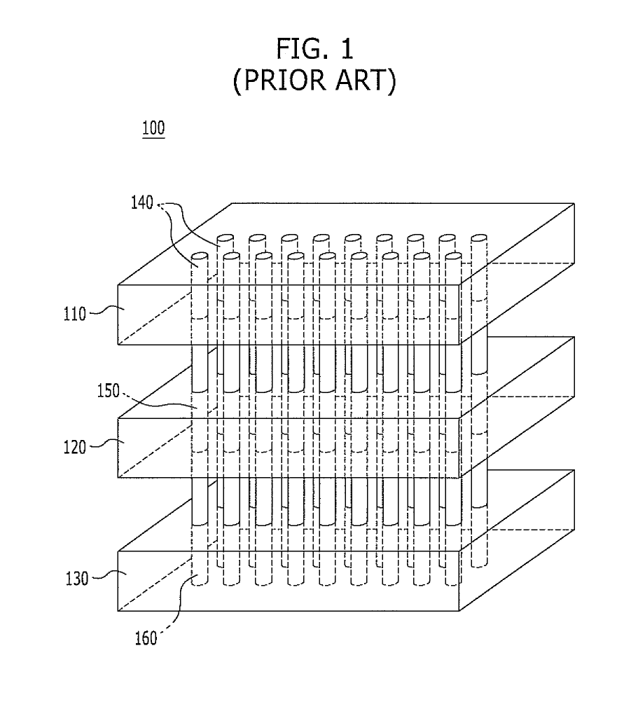

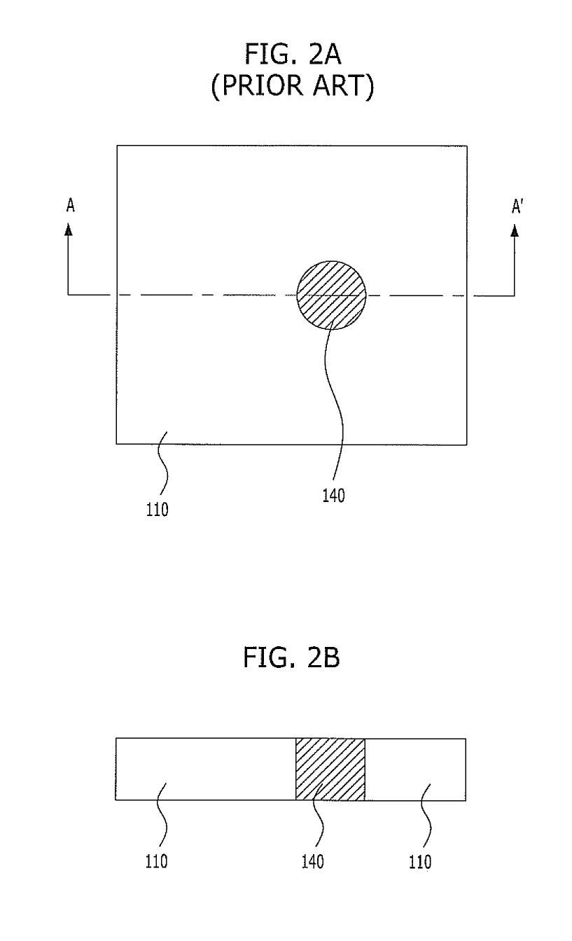

In the following description, a single semiconductor chip and a single TSV vertically passing through the semiconductor chip will be exemplified as an embodiment of a semiconductor integrated circuit. As illustrated in FIG. 1, it is apparent that the semiconductor integrated circuit may include a plurality of stacked semiconductor chips and a plurality of TSVs passing vertically through the semiconductor chips.

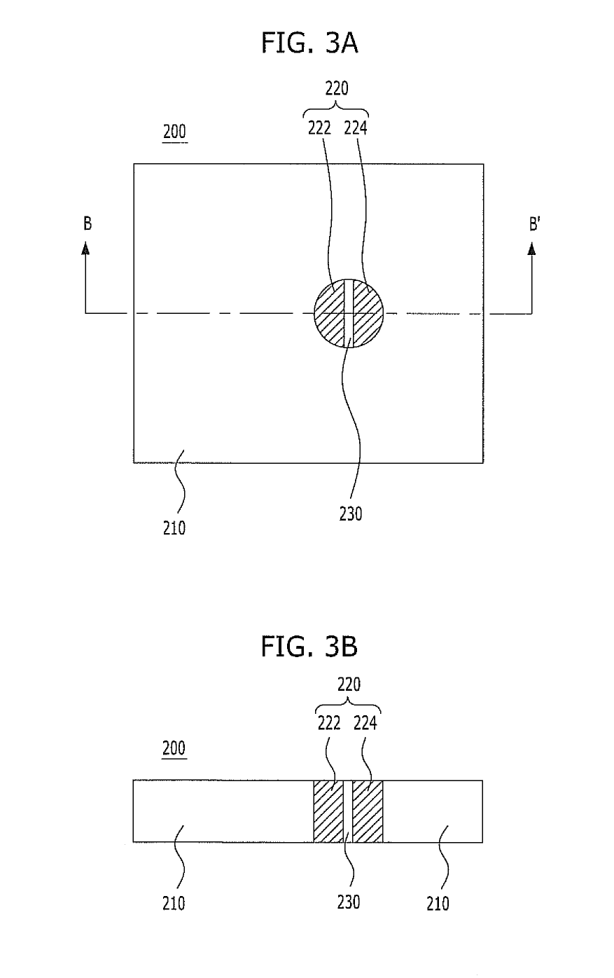

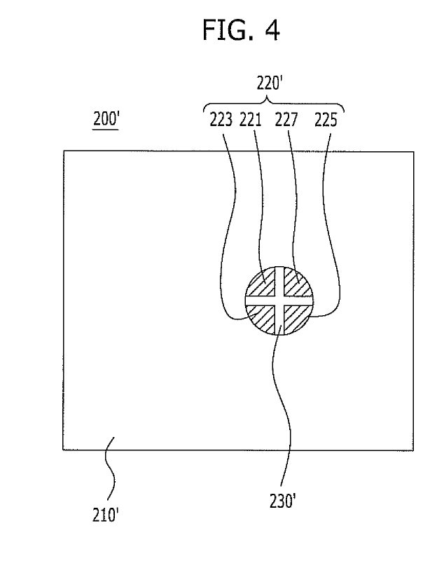

FIG. 3A is a plan view illustrating a semiconductor integrated circuit in accordance with an exemplary embodiment of the present invention, FIG. 3B is a side sectional view taken along line B-B′ of FIG. 3A, and FIG. 4 is a plan view illustrating another shape of an insulator of FIGS. 3A and 3B.

Referring to FIGS. 3A and 3B, the semiconductor integrated circuit 200 may include a semiconductor chip 210, a TSV 220 passing through the semiconductor chip 210, and an insulator 230 arranged inside the TSV 220 to separate the TSV 220 along a plane that is perpendicular to the semiconductor chip 210. The separated TSVs 222, 224 may transmit different data signals or power supply signals.

The semiconductor chip 210 may be a known silicon substrate on which various devices (for example, MOS transistors) are formed. No devices may be arranged within a certain region (hereinafter, referred to as a “non-active region”) around the TSV 220 in the semiconductor chip 210 in order to reduce/minimize a degradation of the semiconductor chip by the TSV 220.

The TSV 220 may transmit data signals or power supply signals between stacked semiconductor chips (not shown). The TSV 220 may be divided, for example, a first via 222 and a second via 224 by the insulator 230, so that two different data signals or power supply signals may be transmitted. The first via 222 and the second via 224 may be formed of a metal, for example, copper (Cu) having good conductivity. Since the first via 222 and the second via 224 may be formed of a metal, and since the insulator 230 may be formed between the first via 222 and the second via 224, a parasitic capacitor may be formed between the first via 222 and the second via 224. When a power supply signal is transmitted through the first via 222 and the second via 224, the parasitic capacitor may have a robustness against power fluctuation and various noises, and thus, the semiconductor integrated circuit 200 may maintain the power supply constantly. In other words, the parasitic capacitor may perform the same function as a reservoir capacitor.

From a plan view, the insulator 230 may have a line shape to separate the TSV 220. Since the thickness of the insulator 230 may determine a capacitance of the parasitic capacitor formed between the first via 222 and the second via 224, the thickness of the insulator 230 may be optimally adjusted according to a dielectric constant of the insulator 230. Further, the insulator 230 may also have a cross shape as illustrated in FIG. 4. In this case, the TSV 220′ may be quadrisected into first to fourth vias 221, 223, 225, and 227, which may transmit four different data signals or power supply signals. Since a parasitic capacitor may also be formed in this case, the above-described advantages of the parasitic capacitor, such as power stabilization, may also be realized.

Meanwhile, although not shown, the TSVs passing through the stacked semiconductor chips may be connected together by bump pads.

In accordance with an exemplary embodiment of the present invention, since two or more data signals and power supply signals may be transmitted through the single TSV, the number of the TSVs may be remarkably reduced. Due to the reduction in the number of the TSVs, the non-active region may also be reduced. Moreover, since the parasitic capacitor may be formed, the number of the reservoir capacitors to be provided in the semiconductor chip may be reduced, and thus, a space efficiency of the semiconductor integrated circuit may be improved.

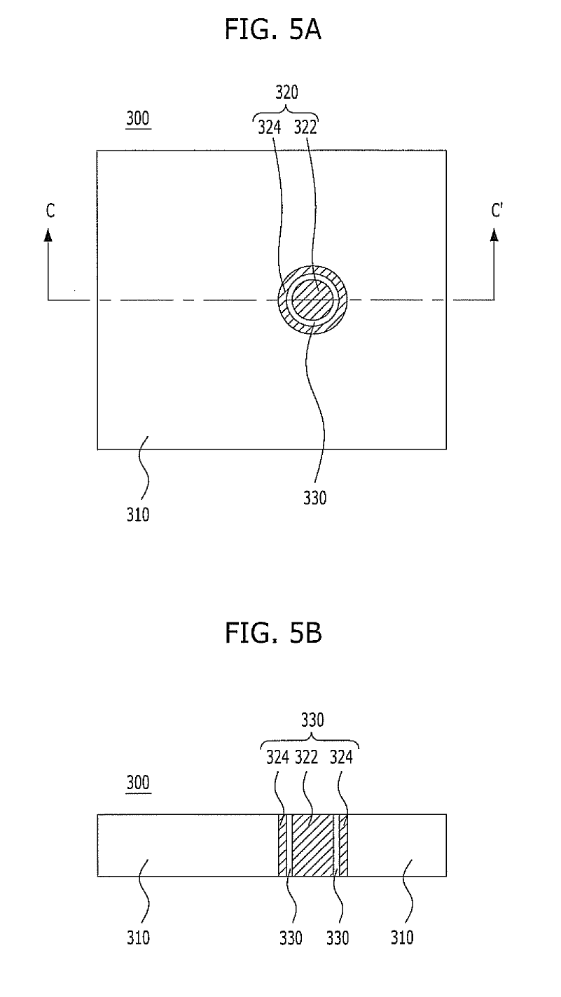

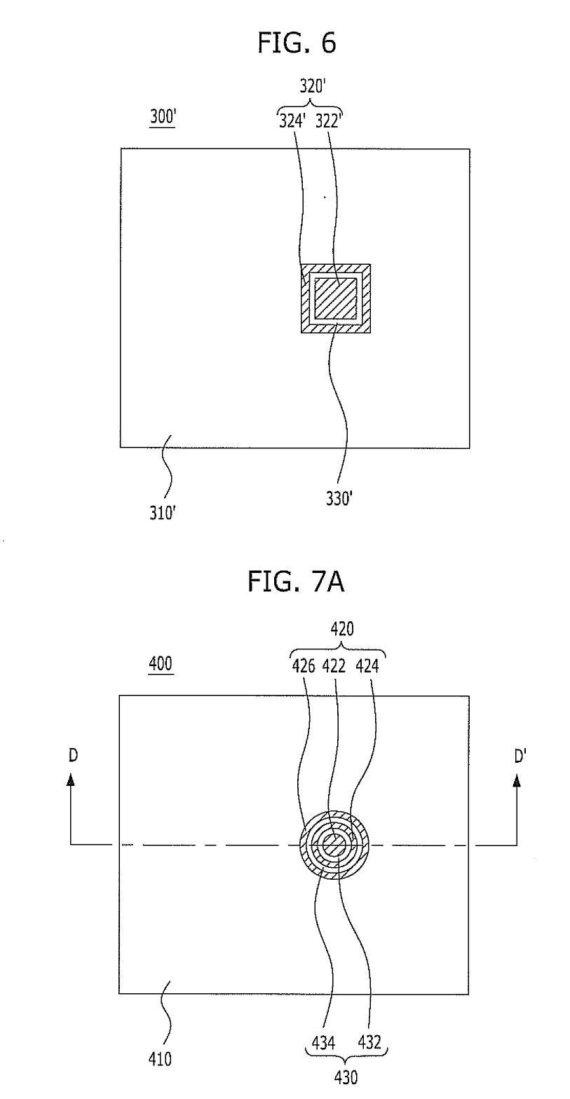

FIG. 5A is a plan view illustrating a semiconductor integrated circuit in accordance with another exemplary embodiment of the present invention, FIG. 5B is a side sectional view taken along line C-C′ of FIG. 5A, and FIG. 6 is a plan view illustrating another shape of an insulator of FIGS. 5A and 5B.

Referring to FIGS. 5A and 5B, the semiconductor integrated circuit 300 may include a semiconductor chip 310, a TSV 320 passing through the semiconductor chip 310, and an insulator 330. The insulator 330 may have a cylindrical shape within the TSV 320 in order to divide the TSV 320. Here, the divided TSVs 320 may transmit different signals.

The semiconductor chip 310 may be a known silicon substrate on which various devices (for example, MOS transistors and reservoir capacitors) are arranged. Further, ideally no devices are arranged within a non-active region around the TSV 320 in the semiconductor chip 310 in order to reduce/minimize a degradation of the semiconductor chip 310 by the TSV 320.

The TSV 320 may transmit data signals or power supply signals between stacked semiconductor chips (not shown). The TSV 320 may include a first via (hereinafter, referred to as an “inner via”) 322 and a second via (hereinafter, referred to as an “outer via”) 324, which are separated by the cylindrical-shaped insulator 330. The inner via 322 may be arranged at the center of the TSV 320, and the outer via 324 may be arranged along the outer circumference of the TSV 320. The inner via 322 and the outer via 324 may be formed of a metal, for example, copper (Cu). Since the inner via 322 and the outer via 324 may be formed of a metal, and since the insulator 330 may be arranged between the inner via 322 and the outer via 324, a parasitic capacitor may be formed between the inner via 322 and the outer via 324. Here, the parasitic capacitor may have two functions. First, when a power supply signal is transmitted through the inner via 322 and the outer via 324, the parasitic capacitor may have robustness against power fluctuation and various noises, and thus, the semiconductor integrated circuit may maintain the power supply constantly. That is, the parasitic capacitor may perform the same function as a reservoir capacitor provided in the semiconductor chip 210. Second, when a signal is transmitted through the inner via 322, the outer via 324 may be used as a shielding line of the inner via 322.

The insulator 330 may have a ring shape to divide the TSV 320 into the inner via 322 and the outer via 324. Since the thickness of the insulator 330 may determine the capacitance of the parasitic capacitor formed between the inner via 322 and the outer via 324, the thickness of the insulator 330 may be optimally adjusted according to a dielectric constant of the insulator 330. Alternatively, the insulator 330 may have a polygonal shape as illustrated in FIG. 6. Here, an insulator 330′ may have a polygonal shape in order to divide a polygonal TSV 320′.

Meanwhile, although not shown, the TSVs passing through the stacked semiconductor chips may be connected together by bump pads.

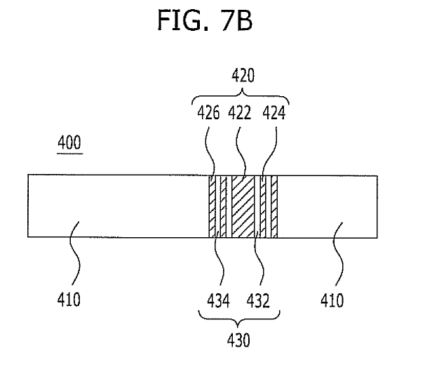

FIG. 7A is a plan view illustrating a semiconductor integrated circuit in accordance with yet another exemplary embodiment of the present invention, and FIG. 7B is a side sectional view taken along line D-D′ of FIG. 7A.

This embodiment is directed to a semiconductor integrated circuit which has at least two insulators and may transmit three or more different data signals or power supply signals.

Referring to FIGS. 7A and 7B, the semiconductor integrated circuit 400 includes a first through-chip via 426 passing through a semiconductor chip 410, a second through-chip via 424 passing through the semiconductor chip 410, wherein the second through-chip via 424 is arranged inside the first through-chip via 426, a third through-chip via 422 passing through the semiconductor chip 410, wherein the third through-chip via 422 is arranged inside the second through-chip via 424, a first insulator 434 arranged between the first through-chip via 426 and the second through-chip via 424, and a second insulator 432 arranged between the second through-chip via 424 and the third through-chip via 422, wherein each of the through-chip vias is configured to transmit different signals.

The semiconductor chip 410 may be a known silicon substrate on which various devices (for example, MOS transistors and reservoir capacitors) are formed. Further, ideally no devices are arranged within a non-active region around the TSV 420 in the semiconductor chip 410 in order to reduce/minimize a degradation of the semiconductor chip 410 by the TSV 420.

The TSV 420 may transmit data signals or power supply signals between stacked semiconductor chips (not shown). The TSV 420 may include a first via 426, a second via 424, and a third via 422, which are separated by cylindrical-shaped first and second insulators 434 and 432. The third via 422 may be arranged at the center of the TSV 420, and the second via 424 may be arranged between the first insulator 434 and the second insulator 432. The first via 426 may be arranged at the outer circumference of the TSV 420. The first to third vias 426, 424 and 422 may be formed of a metal, for example, copper (Cu). Since the first to third vias 426, 424 and 422 may be formed of a metal and the first and second insulators 434 and 432 may be arranged between the first to third vias 426, 424 and 422, a parasitic capacitor may be formed between the first via 426 and the second via 424 and between the second via 424 and the third via 422. As described above, the parasitic capacitor may have two functions. First, when a power supply signal is transmitted through the first to third vias 426, 424 and 422, the parasitic capacitor may have a robustness against power fluctuation and various noises, and thus, the semiconductor integrated circuit 400 may maintain the power supply constantly. That is, the parasitic capacitor may perform the same function as a reservoir capacitor provided in the semiconductor chip 410. Second, when a signal is transmitted through the first via 426 or the second via 424, the second via 424 or the third via 422 may be used as a shielding line of the first via 426 or the second via 424, respectively.

The first and second insulators 434 and 432 may have a ring shape to divide the TSV 420 into the first to third vias 426, 424 and 422. Since the thicknesses of the first and second insulators 434 and 432 may determine the capacitance of the parasitic capacitors formed among the first to third vias 426, 424 and 422, the thickness of the first and second insulators 434 and 432 may be optimally adjusted according to the dielectric constants of the first and second insulators 434 and 432. Here, the first and second insulators 434 and 432 may also have a polygonal shape as well as a ring shape (see FIG. 6).

Meanwhile, although not shown, the TSVs passing through the stacked semiconductor chips may be connected together by bump pads.

In accordance with the exemplary embodiments described, since two or more data signals and power supply signals may be transmitted through the single TSV, the number of the TSVs may be reduced. Due to the reduction in the number of the TSVs, the non-active region may also be reduced. Moreover, since the parasitic capacitor may be formed, the number of the reservoir capacitors to be provided in the semiconductor chip may be reduced, and thus, a space efficiency of the semiconductor integrated circuit may be improved.

Consequently, the entire area of the semiconductor integrated circuit may be reduced/minimized.

While the present invention has been described with respect to the specific embodiments, it will be apparent to those skilled in the art that various changes and modifications may be made without departing from the spirit and scope of the invention as defined in the following claims.

For example, although it has been described in the exemplary embodiments of the present invention that, from a plan view, the insulator has a line shape or a cross shape, it is not limited thereto. Furthermore, the TSVs may be divided with insulators of various shapes to form various numbers of vias within each TSV.

Moreover, although it has been described in the exemplary embodiments of the present invention that the insulator bisects or trisects the TSV, it is not limited thereto. The insulator may also divide the TSV by more than three.

What is claimed is:

1. A semiconductor integrated circuit comprising:
a through-chip via passing through a semiconductor chip; and
an insulator arranged inside the through-chip via to electrically divide the through-chip via, wherein each of the divided through-chip vias is configured to transmit different signals.

2. The semiconductor integrated circuit of claim 1, wherein the through-chip via comprises a through-silicon via (TSV).

3. The semiconductor integrated circuit of claim 1, wherein the insulator is arranged inside the through-chip via to divide the through-chip via along a plane that is perpendicular to the semiconductor chip.

4. The semiconductor integrated circuit of claim 3, wherein the insulator has a line shape from a plan view.

5. The semiconductor integrated circuit of claim 3, wherein the insulator has a cross shape from a plan view.

6. The semiconductor integrated circuit of claim 3, wherein the through-chip via comprises a through-silicon via (TSV).

7. A semiconductor integrated circuit comprising:
a through-chip via passing through a semiconductor chip; and
an insulator arranged inside the through-chip via, the insulator having a cylindrical shape in order to divide the through-chip via, wherein each of the divided through-chip vias is configured to transmit different signals.

8. The semiconductor integrated circuit of claim 7, wherein the insulator has a ring shape from a plan view.

9. The semiconductor integrated circuit of claim 7, wherein the insulator has a polygonal shape from a plan view.

10. The semiconductor integrated circuit of claim 7, wherein the through-chip via comprises a through-silicon via (TSV).

11. A semiconductor integrated circuit comprising:
a first through-chip via passing through a semiconductor chip;
a second through-chip via passing through the semiconductor chip, wherein the second through-chip via is arranged inside the first through-chip via;
a third through-chip via passing through the semiconductor chip, wherein the third through-chip via is arranged inside the second through-chip via;
a first insulator arranged between the first through-chip via and the second through-chip via; and
a second insulator arranged between the second through-chip via and the third through-chip via,
wherein each of the through-chip vias is configured to transmit different signals.

12. The semiconductor integrated circuit of claim 11, wherein the first insulator has a cylindrical shape to electrically separate the first and second through-chip vias.

13. The semiconductor integrated circuit of claim 11, wherein the second insulator has a cylindrical shape to electrically separate the first and the second through-chip vias.

14. The semiconductor integrated circuit of claim 11, wherein the first insulator has a ring shape from a plan view.

15. The semiconductor integrated circuit of claim 11, wherein the second insulator has a ring shape from a plan view.

16. The semiconductor integrated circuit of claim 11, wherein the first insulator has a polygonal shape from a plan view.

17. The semiconductor integrated circuit of claim 11, wherein the second insulator has a polygonal shape from a plan view.
